(19) United States
(12) Patent Application Publication
(10) Pub. No.: US 2025/0248218 A1
(43) Pub. Date: Jul. 31, 2025

(54) DISPLAY SUBSTRATE AND METHOD FOR MANUFACTURING THE SAME, AND DISPLAY APPARATUS

(71) Applicants: YUNNAN INVENSIGHT OPTOELECTRONICS TECHNOLOGY CO., LTD., Kunming (CN); BOE TECHNOLOGY GROUP CO., LTD., Beijing (CN)

(72) Inventors: Yifan Yang, Beijing (CN); Yanming Wang, Beijing (CN); Xiaoyan Hou, Beijing (CN); He Yuan, Beijing (CN); Shiwei Wang, Beijing (CN); Zhiqiang Wang, Beijing (CN); Dacheng Zhang, Beijing (CN)

(21) Appl. No.: 18/693,148

(22) PCT Filed: Jul. 28, 2023
(86) PCT No.: PCT/CN2023/109802

§ 371 Date: Mar. 18, 2024

(51) Int. Cl. H10K 59/122; H10K 59/12; H10K 59/80

(52) U.S. Cl. CPC H10K 59/122; H10K 59/1201; H10K 59/879

(57) ABSTRACT

Provided is a display substrate, including: a substrate; a first electrode layer, a pixel defining layer, a first film layer group, and a second film layer group, which are disposed on the base substrate along a direction away from the base substrate. The first film layer group includes a first portion and a second portion, where an orthographic projection of the first portion on the base substrate at least partially overlaps with an orthographic projection of the first electrode layer, an orthographic projection of the second portion on the base substrate at least partially overlaps with an orthographic projection of the pixel defining layer on the base substrate, and the first portion and the second portion are interrupted. The second film layer group includes a first portion and a second portion, which extend continuously.

### CROSS-REFERENCE TO RELATED APPLICATION

This application is a Section 371 National Stage Application of International Application No. PCT/CN2023/109802, filed Jul. 28, 2023, entitled “DISPLAY SUBSTRATE AND METHOD FOR MANUFACTURING THE SAME, AND DISPLAY APPARATUS”, which is incorporated herein by reference in its entirety.

### TECHNICAL FIELD

The present disclosure relates to a field of display technology, in particular to a display substrate and a method for manufacturing the same, and a display apparatus.

### BACKGROUND

Organic light-emitting diode (OLED) devices have attracted much attention due to the advantages such as self-luminescence, rich color, fast response speed, wide viewing angle, light weight, thin thickness, low power consumption and flexible display, and nowadays are widely used in devices such as mobile phones, televisions, and wearable devices. With the development of OLED technology, requirements for resolution and brightness of OLED screens are growing higher and higher. Some premium OLED screens is required to have a resolution of over 3000 PPI (pixel per inch) and a brightness of over 5000 nits. designing and manufacturing OLED display products with high brightness and high resolution is one of the important research topics for R&D personnel.

### SUMMARY

In an aspect, a display substrate is provided, including: a base substrate; a first electrode layer disposed on the base substrate, where the first electrode layer includes a plurality of first electrode patterns, the plurality of first electrode patterns are arranged in an array along a first direction and a second direction on the base substrate, and the plurality of first electrode patterns are spaced apart from each other along each of the first direction and the second direction; a pixel defining layer disposed on a side of the first electrode layer away from the base substrate, where the pixel defining layer includes a plurality of pixel defining structures, the plurality of pixel defining structures are arranged in an array along the first direction and the second direction on the base substrate and define a plurality of pixel openings, and the plurality of pixel openings each expose a portion of a respective one of the plurality of first electrode patterns; a first film layer group disposed on a side of the pixel defining layer away from the base substrate, where the first film layer group includes at least one film layer; and a second film layer group disposed on a side of the first film layer group away from the base substrate, where the second film layer group includes at least one film layer, where the first film layer group includes a first portion and a second portion, an orthographic projection of the first portion of the first film layer group on the base substrate at least partially overlaps with an orthographic projection of at least one first electrode pattern on the base substrate, an orthographic projection of the second portion of the first film layer group on the base substrate at least partially overlaps with an orthographic projection of at least one pixel defining structure on the base substrate, and the first portion of the first film layer group and the second portion of the first film layer group are interrupted; and the second film layer group includes a first portion and a second portion, where an orthographic projection of the first portion of the second film layer group at least partially overlaps with an orthographic projection of at least one first electrode pattern on the base substrate, an orthographic projection of the second portion of the second film layer group on the base substrate at least partially overlaps with an orthographic projection of at least one pixel defining structure on the base substrate, and the first portion of the second film layer group and the second portion of the second film layer group extend continuously.

According to some exemplary embodiments, the pixel defining structure includes a top surface away from the base substrate, and the top surface has a shape of convex cambered surface.

According to some exemplary embodiments, the first portion of the first film layer group includes an end proximate to the pixel defining structure, the end is covered by the pixel defining structure, and the end is inserted between the pixel defining structure and the first electrode layer.

According to some exemplary embodiments, a thickness of the end is less than a thickness of a remaining part of the first portion of the first film layer group other than the end; and/or, the thickness of the end is less than a thickness of the second portion of the first film layer group.

According to some exemplary embodiments, the orthographic projection of the first portion of the first film layer group on the base substrate partially overlaps with the orthographic projection of the second portion of the first film layer group on the base substrate.

According to some exemplary embodiments, a part of the second film layer group is filled in a gap between the first portion of the first film layer group and the second portion of the first film layer group.

According to some exemplary embodiments, the part of the second film layer group filled in the gap is in direct contact with a top surface of the pixel defining structure.

According to some exemplary embodiments, a tangent plane of a top surface of the pixel defining structure at a first position has an included angle with respect to a first surface of the base substrate, the included angle being less than or equal to 60 degrees, where the first surface of the base substrate is a surface of the base substrate facing the first electrode layer, and the first position is a position where the top surface of the pixel defining structure contacts with the first film layer group.

According to some exemplary embodiments, the display substrate includes a second electrode layer disposed on the side of the first film layer group away from the base substrate, and the second film layer group includes at least the second electrode layer.

According to some exemplary embodiments, the display substrate further includes: a hole injection layer disposed on the side of the first electrode layer away from the base substrate; a hole transport layer disposed on a side of the hole injection layer away from the base substrate; an electron barrier layer disposed on a side of the hole transport layer away from the base substrate; a light-emitting layer disposed on a side of the electron barrier layer away from the base substrate; a hole barrier layer disposed on a side of the light-emitting layer away from the base substrate; an electron transport layer disposed on a side of the hole barrier layer away from the base substrate; an electron injection layer disposed on a side of the electron transport layer away from the base substrate; and a second electrode layer disposed on a side of the electron injection layer away from the base substrate. The first film layer group includes the hole injection layer and the hole transport layer, and/or, the second film layer group includes the electron barrier layer, the light-emitting layer, the hole barrier layer, the electron transport layer, the electron injection layer and the second electrode layer.

According to some exemplary embodiments, the display substrate further includes: a first stacked film layer group disposed on the side of the first electrode layer away from the base substrate; a charge generation layer disposed on a side of the first stacked film layer group away from the base substrate; a second stacked film layer group disposed on a side of the charge generation layer away from the base substrate; and a second electrode layer disposed on a side of the second stacked film layer group away from the base substrate. The first film layer group includes the first stacked film layer group and the charge generation layer, and/or, the second film layer group includes the second stacked film layer group and the second electrode layer.

According to some exemplary embodiment, the first stacked film layer group includes: a hole injection layer disposed on the side of the first electrode layer away from the base substrate; a hole transport layer disposed on a side of the hole injection layer away from the base substrate; an electron barrier layer disposed on a side of the hole transport layer away from the base substrate; a light-emitting layer disposed on a side of the electron barrier layer away from the base substrate; a hole barrier layer disposed on a side of the light-emitting layer away from the base substrate; an electron transport layer disposed on a side of the hole barrier layer away from the base substrate; and an electron injection layer disposed on a side of the electron transport layer away from the base substrate, and/or, the second stacked film layer group includes: a hole injection layer disposed on the side of the charge generation layer away from the base substrate; a hole transport layer disposed on a side of the hole injection layer away from the base substrate; an electron barrier layer disposed on a side of the hole transport layer away from the base substrate; a light-emitting layer disposed on a side of the electron barrier layer away from the base substrate; a hole barrier layer disposed on a side of the light-emitting layer away from the base substrate; an electron transport layer disposed on a side of the hole barrier layer away from the base substrate; and an electron injection layer disposed on a side of the electron transport layer away from the base substrate.

According to some exemplary embodiments, the display substrate further includes: a first stacked film layer group disposed on the side of the first electrode layer away from the base substrate; a first charge generation layer disposed on a side of the first stacked film layer group away from the base substrate; a second stacked film layer group disposed on a side of the first charge generation layer away from the base substrate; a second charge generation layer disposed on a side of the second stacked film layer group away from the base substrate; a third stacked film layer group disposed on a side of the second charge generation layer away from the base substrate; and a second electrode layer disposed on a side of the third stacked film layer group away from the base substrate. The first film layer group includes the first stacked film layer group, the first charge generation layer, the second stacked film layer group and the second charge generation layer, and/or, the second film layer group includes the third stacked film layer group and the second electrode layer.

According to some exemplary embodiments, the first stacked film layer group includes: a hole injection layer disposed on a side of the first electrode layer away from the base substrate; a hole transport layer disposed on a side of the hole injection layer away from the base substrate; an electron barrier layer disposed on a side of the hole transport layer away from the base substrate; a light-emitting layer disposed on a side of the electron barrier layer away from the base substrate; a hole barrier layer disposed on a side of the light-emitting layer away from the base substrate; an electron transport layer disposed on a side of the hole barrier layer away from the base substrate; and an electron injection layer disposed on a side of the electron transport layer away from the base substrate, and/or, the second stacked film layer group includes: a hole injection layer disposed on the side of the first charge generation layer away from the base substrate; a hole transport layer disposed on a side of the hole injection layer away from the base substrate; an electron barrier layer disposed on a side of the hole transport layer away from the base substrate; a light-emitting layer disposed on a side of the electron barrier layer away from the base substrate; a hole barrier layer disposed on a side of the light-emitting layer away from the base substrate; an electron transport layer disposed on a side of the hole barrier layer away from the base substrate; and an electron injection layer disposed on a side of the electron transport layer away from the base substrate, and/or, the third stacked film layer group includes: a hole injection layer disposed on the side of the second charge generation layer away from the base substrate; a hole transport layer disposed on a side of the hole injection layer away from the base substrate; an electron barrier layer disposed on a side of the hole transport layer away from the base substrate; a light-emitting layer disposed on a side of the electron barrier layer away from the base substrate; a hole barrier layer disposed on a side of the light-emitting layer away from the base substrate; an electron transport layer disposed on a side of the hole barrier layer away from the base substrate; and an electron injection layer disposed on a side of the electron transport layer away from the base substrate.

According to some exemplary embodiments, the pixel defining layer includes a photoresist material.

According to some exemplary embodiments, the photoresist material is reflowable after being softened, and a softening temperature of the photoresist material is lower than a glass transition temperature of each film layer of the first film layer group and a glass transition temperature of each film layer of the second film layer group.

According to some exemplary embodiments, the display substrate further includes: a plurality of micro lenses disposed on a side of the second electrode layer away from the base substrate; and each of orthographic projections of the plurality of micro lenses on the base substrate is located within an orthographic projection of a respective one of the plurality of pixel openings on the base substrate.

According to some exemplary embodiments, a material of the plurality of micro lenses is the same as a material of at least a part of the pixel defining layer.

According to some exemplary embodiments, a curvature of at least one of the micro lenses is less than a curvature of the pixel defining structure.

According to some exemplary embodiments, the display substrate further includes a plurality of color film layers, and the plurality of color film layers are located between the pixel defining layer and a layer in which the plurality of micro lenses are located. An orthographic projection of a micro lens on the base substrate and an orthographic projection of a pixel defining structure adjacent to the micro lens on the base substrate have a first overlap portion, orthographic projections of any two adjacent color film layers on the base substrate have a second overlap portion, and a width of the first overlap portion in the first direction is greater than a width of the second overlap portion in the first direction.

According to some exemplary embodiments, the pixel defining layer includes a first sub-pixel defining layer and a second sub-pixel defining layer, the second sub-pixel defining layer is located on a side of the first sub-pixel defining layer away from the base substrate, and an orthographic projection of the second sub-pixel defining layer on the base substrate at least partially overlaps with an orthographic projection of the first sub-pixel defining layer on the base substrate. The first sub-pixel defining layer includes a photoresist material, and the second sub-pixel defining layer includes an inorganic material.

In another aspect, a display apparatus is provided. The display apparatus includes the display substrate as described above.

In yet another aspect, a method for manufacturing a display substrate is provided. The method includes: forming a first electrode material layer on a base substrate, and performing a patterning process on the first electrode material layer, so as to form a first electrode layer including a plurality of first electrode patterns, where the plurality of first electrode patterns are arranged in an array along a first direction and a second direction on the base substrate, and the plurality of first electrode patterns are spaced apart from each other along each of the first direction and the second direction; forming a pixel defining material layer on a side of the first electrode layer away from the base substrate, and performing a patterning process on the pixel defining material layer, so as to form a pixel defining layer including a plurality of pixel defining structures, where the plurality of pixel defining structures are arranged in an array along the first direction and the second direction on the base substrate, the plurality of pixel defining structures define a plurality of pixel openings, and the plurality of pixel openings each expose a portion of a respective one of the plurality of first electrode patterns; forming a first film layer group on a side of the pixel defining layer away from the base substrate by using a first evaporation process, where the first film layer group includes at least one film layer; performing a reflow process on the base substrate formed with the pixel defining layer and the first film layer group; and forming a second film layer group on a side of the first film layer group away from the base substrate by using a second evaporation process, where the second film layer group includes at least one film layer. The first film layer group includes a first portion and a second portion, an orthographic projection of the first portion of the first film layer group on the base substrate at least partially overlaps with an orthographic projection of at least one first electrode pattern on the base substrate, an orthographic projection of the second portion of the first film layer group on the base substrate at least partially overlaps with an orthographic projection of at least one pixel defining structure on the base substrate, and the first portion of the first film layer group and the second portion of the first film layer group are interrupted. The second film layer group includes a first portion and a second portion, where an orthographic projection of the first portion of the second film layer group on the base substrate at least partially overlaps with an orthographic projection of at least one first electrode pattern on the base substrate, an orthographic projection of the second portion of the second film layer group on the base substrate at least partially overlaps with an orthographic projection of at least one pixel defining structure on the base substrate, and the first portion of the second film layer group and the second portion of the second film layer group extend continuously.

According to some exemplary embodiments, the forming a pixel defining material layer on a side of the first electrode layer away from the base substrate, and performing a patterning process on the pixel defining material layer, so as to form a pixel defining layer including a plurality of pixel defining structures, includes: coating a photoresist material on the side of the first electrode layer away from the base substrate; and performing an exposure process and a development process on the photoresist material, so as to form the plurality of pixel defining structures.

According to some exemplary embodiments, the photoresist material is reflowable after being softened, and a softening temperature of the photoresist material is lower than a glass transition temperature of each film layer of the first film layer group and a glass transition temperature of each film layer of the second film layer group.

According to some exemplary embodiments, the method further includes: before the first evaporation process, performing a baking process on the base substrate formed with the pixel defining layer, where a softening temperature of the photoresist material is higher than a baking temperature in the baking process.

According to some exemplary embodiments, before the reflow process, a top surface of the pixel defining structure has an included angle with respect to a first surface of the base substrate at a second position, the included angle being greater than or equal to 85 degrees, where the first surface of the base substrate is a surface of the base substrate facing the first electrode layer, and the second position is a position where the top surface of the pixel defining structure contacts with the first electrode layer; and/or, after the reflow process, a tangent plane of the top surface of the pixel defining structure at a first position has an included angle with respect to the first surface of the base substrate, the included angle being less than or equal to 60 degrees, where the first surface of the base substrate is the surface of the base substrate facing the first electrode layer, and the first position is a position where the top surface of the pixel defining structure contacts with the first film layer group.

### BRIEF DESCRIPTION OF THE DRAWINGS

The above contents, other objectives, features and advantages of the present disclosure will be clearer through the following description of embodiments of the present disclosure with reference to the accompanying drawings, in which:

FIG. 1 shows a schematic partial top view of a display substrate according to some exemplary embodiments of the present disclosure;

FIG. 2 shows a schematic cross-sectional view of a display substrate according to some exemplary embodiments of the present disclosure, which is taken along line AA′ in FIG. 1;

FIG. 3 shows a schematic cross-sectional view of a display substrate taken along line AA′ in FIG. 1, according to some other exemplary embodiments of the present disclosure;

FIG. 4 shows a schematic diagram of a structure of a single-layer OLED device of a light-emitting unit according to some exemplary embodiments of the present disclosure;

FIG. 5 shows a schematic diagram of a structure of a double-layer OLED device of a light-emitting unit according to some exemplary embodiments of the present disclosure;

FIG. 6 shows a schematic diagram of a structure of a first stacked film layer group T1 in FIG. 5;

FIG. 7 shows a schematic diagram of a structure of a second stacked film layer group T2 in FIG. 5;

FIG. 8 shows a schematic diagram of a structure of a three-layer OLED device of a light-emitting unit according to some exemplary embodiments of the present disclosure;

FIG. 9 shows a schematic diagram of a structure of a third stacked film layer group in the three-layer OLED device in FIG. 8;

FIG. 10A shows a schematic partial cross-sectional view of a display substrate according to some other exemplary embodiments of the present disclosure; FIG. 10B shows a schematic partial cross-sectional view of a display substrate according to some other exemplary embodiments of the present disclosure, in which a color film layer is shown; FIG. 10C shows a schematic partial cross-sectional view of a display substrate according to some other exemplary embodiments of the present disclosure, in which a first sub-pixel defining layer and a second sub-pixel defining layer are shown;

FIG. 11A to FIG. 11F show a method for manufacturing a display substrate according to an exemplary embodiment of the present disclosure;

FIG. 12 shows a flowchart of manufacturing a pixel defining structure of a display substrate according to some exemplary embodiments of the present disclosure; and

FIG. 13 shows a partial cross-sectional view of a base substrate before a reflow process is performed, according to some exemplary embodiments of the present disclosure.

It will be noted that, for the sake of clarity, in the accompanying drawings used to describe the embodiments of the present disclosure, dimensions of layers, structures or areas may be enlarged or reduced, that is, these drawings are not drawn according to the actual scale.

### DETAILED DESCRIPTION OF EMBODIMENTS

For clarity of the objectives, technical solutions and advantages of the embodiments of the present disclosure clearer, the technical solutions in the embodiments of the present disclosure will be described clearly and completely in combination with the accompanying drawings of the embodiments of the present disclosure. Obviously, the described embodiments are only part of the embodiments of the present disclosure, not all of them. Based on the embodiments of the present disclosure provided, all other embodiments obtained by those of ordinary skill in the art without creative labor fall within the scope of protection of the present disclosure.

It will be noted that, in the accompanying drawings, a dimension and a relative dimension of the elements may be exaggerated for clarity and/or description. In this way, dimensions and relative dimensions of the various elements are not necessarily limited to those shown in the accompanying drawings. In the specification and the accompanying drawings, the same or similar reference number represents the same or similar component.

Unless otherwise defined, the technical or scientific terms used herein shall have general meanings understood by those of ordinary skill in the art. The terms “first”, “second”, and the like used herein do not indicate any order, quantity, or importance, but are only for distinguishing different components. The term “comprise”, “include”, or the like means that a component or object before this term, covers a component or object listed after this term and its equivalents, rather than excluding other components or objects.

Herein, unless otherwise specified, directional terms such as “upper”, “lower”, “left”, “right”, “inside”, “outside” may be used to represent orientation or positional relationships based on the drawings, only for the purpose of describing the present disclosure, rather than indicating or implying that the device, element or component referred to must have a specific orientation, be constructed or operated in a specific orientation. It will be understood that when the absolute position of the described object changes, the relative positional relationship they represent may also change accordingly. Therefore, these directional terms may not be understood as restrictions on the present disclosure.

It will be noted that the expression “same layer” refers to a layer structure which is formed by forming a layer used to form a specific pattern by the same film-forming process, and then patterning the layer by using the same mask through one patterning process. According to the difference between the specific patterns, the patterning process may include multiple exposure, development or etching processes, and the specific pattern in the formed layer structure may be continuous or discontinuous. That is, multiple elements, components, structures and/or parts located in the “same layer” are made of the same material and formed by the same patterning process. Generally, multiple elements, components, structures and/or parts located in the “same layer” have substantially the same thicknesses.

Those skilled in the art will understand that herein, unless otherwise specified, the expression “height” or “thickness” refers to a dimension of a surface of each film layer along a direction perpendicular to the display substrate, i.e., a dimension along a light exit direction of the display substrate, or referred to as a dimension along a normal direction of the display apparatus.

Herein, directional expressions such as “first direction” and “second direction” are used to describe different directions along pixel units, such as a vertical direction of the pixel units and a horizontal direction of the pixel units, or a row direction of sub-pixel arrangements and a column direction of sub-pixel arrangements. It will be understood that such representation is only an illustrative description rather than a limitation on the present disclosure.

Due to characteristics such as self-luminescence, low power consumption, high color gamut and flexibility, OLEDs (organic light-emitting diode) are applicable for manufacturing displays with premium display effect, and nowadays have been widely used in apparatus such as mobile phones, televisions and wearable devices. As the requirements for resolution and brightness of OLED screens are getting higher and higher, silicon-based OLED devices and Tandem OLED devices come into use. For example, the brightness of the silicon-based OLEDs exceeds 5000 nits, and the sub-pixel pitch reaches the level of 1 micron. However, the use of the tandem technology and the reduction of the pixel pitch make the lateral electricity leakage between pixels extremely prominent. In the manufacturing process of the existing conventional OLED displays, the lateral electricity leakage is mainly controlled by adjustment to the pixel pitch and adjustment to organic film materials with high conductivity. For products using the tandem device structure and silicon-based products with extremely high PPI (pixel per inch) requirements, the pixel defining layer (PDL) is required to be designed with a special structure to minimize the cross color and light leakage caused by the lateral electricity leakage.

Currently, the PDL is generally formed into a structure such as a special protrusion, a groove and an inverted trapezoid to block the lateral electricity leakage of the organic films, and a contour structure of the PDL is usually completely cured before evaporation, resulting in that the continuity of all film layers subsequently formed close to the PDL is disrupted. The disruption of the continuity of a cathode metal in the device will lead to an increase of a cathode voltage, a decrease of light emission efficiency of the device, and even a serious problem such as a black cluster or a short circuit between the anode and the cathode. Therefore, for breakthroughs in high-end OLED display technology, it is extremely important to develop a PDL solution that may effectively control the lateral electricity leakage between pixels without disrupting the continuity of the cathode.

In the embodiments of the present disclosure, a PDL material with reflow property is adopted. An evaporation process is divided into a first evaporation process and a second evaporation process. A first evaporation stage is completed by using the first evaporation process, where a material with high conductivity is evaporated, including a hole injection material, a hole transfer material, a charge generation layer material, etc. The first evaporation process is completed before a reflow process is performed on the PDL material, ensuring that the highly conductive material is interrupted at the PDL material in the first evaporation stage. Then, the reflow process is performed on the PDL material, so that a contour of the PDL structure is rounded. Next, the second evaporation process is performed, and a second evaporation stage is completed by using the second evaporation process. The second evaporation stage includes evaporating all the other OLED film layers other than those evaporated in the first evaporation stage, and the PDL structure with the rounded contour greatly ensures the continuity of an entire surface of the cathode metal after the second evaporation stage is performed. In the embodiments of the present disclosure, by using the PDL reflow technology, it is possible to effectively interrupt the highly conductive materials between the pixels so as to control the lateral electricity leakage between the pixels, while ensuring the continuity of the entire surface of the cathode in the second evaporation stage, thereby facilitating the realization of an OLED design of high brightness and high resolution.

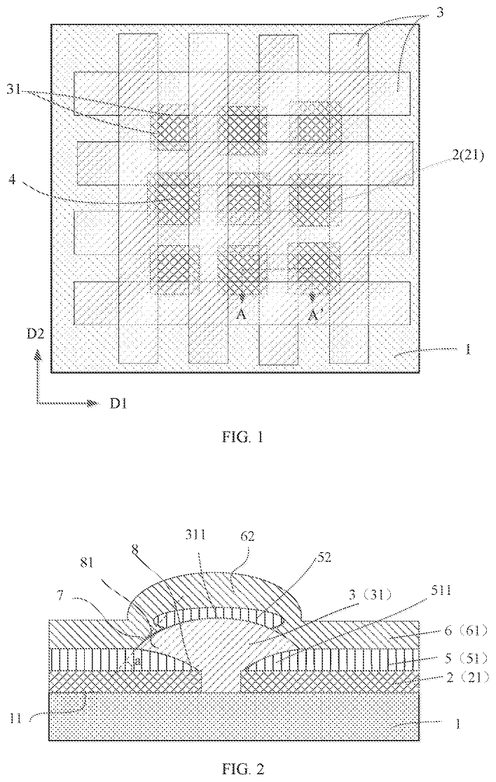

FIG. 1 shows a schematic partial top view of a display substrate according to some exemplary embodiments of the present disclosure. FIG. 2 shows a schematic cross-sectional view of a display substrate according to some exemplary embodiments of the present disclosure, which is taken along line AA′ in FIG. 1.

With reference to FIG. 1 and FIG. 2, the display substrate includes: a base substrate 1; a first electrode layer 2 disposed on the base substrate 1, where the first electrode layer 2 includes a plurality of first electrode patterns 21, the plurality of first electrode patterns 21 are arranged in an array along a first direction D1 and a second direction D2 on the base substrate 1, and the plurality of first electrode patterns 21 are spaced apart from each other along the first direction D1 and the second direction D2; and a pixel defining layer 3 disposed on a side of the first electrode layer 2 away from the base substrate 1, where the pixel defining layer 3 includes a plurality of pixel defining structures 31, the plurality of pixel defining structures are arranged in an array along the first direction D1 and the second direction D2 on the base substrate 1, the plurality of pixel defining structures 31 define a plurality of pixel openings 4, and the plurality of pixel openings 4 each expose a portion of a respective one of the plurality of first electrode patterns 21.

In the embodiment, at least one pixel opening is provided with a light-emitting unit which may emit one of red light, green light or blue light, and the light-emitting unit may be a single-layer OLED device or a Tandem OLED device.

It is worth noting that the embodiments of the present disclosure do not impose any special limitation on the design of the pixel opening 4. For example, although the accompanying figures schematically show that the pixel opening 4 is in a shape of square, in other embodiments, the pixel opening may also be in various shapes such as rectangle, ellipse, circle, and triangle. In addition, light-emitting units of different colors corresponding to different pixel openings may adopt various arrangements known in the art, which will not be specifically limited in the embodiments of the present disclosure.

With reference to FIG. 2, the display substrate further includes a first film layer group 5 disposed on a side of the pixel defining layer 3 away from the base substrate 1, where the first film layer group 5 includes at least one film layer; and a second film layer group 6 disposed on a side of the first film layer group 5 away from the base substrate 1, where the second film layer group includes at least one film layer. The first film layer group 5 includes a first portion 51 and a second portion 52. An orthographic projection of the first portion 51 of the first film layer group on the base substrate 1 at least partially overlaps with an orthographic projection of at least one first electrode pattern 21 on the base substrate 1. An orthographic projection of the second portion 52 of the first film layer group on the base substrate 1 at least partially overlaps with an orthographic projection of at least one pixel defining structure 31 on the base substrate 1. The first portion 51 of the first film layer group and the second portion 52 of the first film layer group are interrupted. The second film layer group 6 includes a first portion 61 and a second portion 62. An orthographic projection of the first portion 61 of the second film layer group at least partially overlaps with the orthographic projection of the at least one first electrode pattern 21 on the base substrate. An orthographic projection of the second portion 62 of the second film layer group on the base substrate at least partially overlaps with the orthographic projection of the at least one pixel defining structure 31 on the base substrate. The first portion 61 of the second film layer group and the second portion 62 of the second film layer group extend continuously.

In the embodiments, the evaporation process of the OLED device is divided into two stages. A first evaporation process is used to complete a first evaporation stage, so as to form the first film layer group 5. A second evaporation process is used to complete a second evaporation stage, so as to form the second film layer group 6. The first evaporation process is used to complete the evaporation of materials with high conductivity in the OLED device, so as to form the first film layer group 5. The first film layer group 5 includes film layers such as a hole injection layer, a hole transport layer, and a charge generation layer. Since the first evaporation process is performed before a reflow process is performed on the pixel defining layer 3, and at this time, the pixel defining layer 3 has not yet formed with an arc top surface as shown in FIG. 2, the first film layer group 5 is interrupted by the pixel defining structure 31 in the first evaporation stage, resulting in forming two portions, which are the first portion 51 of the first film layer group and the second portion 52 of the first film layer group, respectively.

The pixel defining layer 3 includes a material which is reflowable after being softened. After completing the first evaporation stage, the reflow process is performed on the pixel defining layer 3, so that the contour of the pixel defining structure 31 is rounded after the reflow process. The reflow process includes high-temperature treatment, ultraviolet irradiation, and a combination of ultraviolet irradiation and high-temperature treatment. The reflow process is performed in a vacuum chamber integrated with an evaporator. When performing the reflow process, the pixel defining structure 31 is gradually softened and deforms. By controlling the conditions of the reflow process, the contour of the pixel defining structure formed using the reflow process may be adjusted, so as to round the contour of the pixel defining structure 31. Since at least part of the second portion 52 of the first film layer group formed during the first evaporation stage of the material is on the pixel defining structure 31, when performing the reflow process, at least part of the second portion 52 of the first film layer group deforms as the pixel defining structure 31 deforms. Since fluidity of the pixel defining structure 31 is greater than that of the second portion 52 of the first film layer group, after performing the reflow process, the first portion 51 of the first film layer group and the second portion 52 of the first film layer group are still interrupted by the pixel defining structure 31. Therefore, after the first evaporation stage and the reflow process are completed, the orthographic projection of the first portion 51 of the formed first film layer group on the base substrate at least partially overlaps with the orthographic projection of at least one first electrode patterns 21 on the base substrate, the orthographic projection of the second portion 52 of the first film layer group on the base substrate 1 at least partially overlaps with the orthographic projection of at least one pixel defining structures 31 on the base substrate 1, and the first portion 51 of the first film layer group and the second portion 52 of the first film layer group are interrupted.

With continued reference to FIG. 2, the second film layer group 6 is formed by using the second evaporation process. The second evaporation process is performed after the reflow process is performed on the pixel defining structure 31. The second evaporation process is used to complete the second evaporation stage, and the second evaporation stage includes evaporating all the other OLED film layers other than those evaporated in the first evaporation stage. The second film layer group 6 includes the first portion 61 and the second portion 62. The orthographic projection of the first portion 61 of the second film layer group on the base substrate at least partially overlaps with the orthographic projection of at least one first electrode pattern 21 on the base substrate 1, the orthographic projection of the second portion 62 of the second film layer group on the base substrate 1 at least partially overlaps with the orthographic projection of at least one pixel defining structure 31 on the base substrate 1. Since the second film layer group 6 is formed after the reflow process, and the pixel defining structure 31 has formed into the rounded shape with the arc top at this time, the first portion 61 of the second film layer group and the second portion 62 of the second film layer group extend continuously. The second film layer group may include a cathode of the OLED device. Since the second film layer group 6 is continuous, the cathode manufactured is also continuous correspondingly, so that the voltage of the OLED device may be reduced, and the light emission efficiency of the OLED device may be therefore improved, thereby facilitating the realization of high brightness and high resolution display of the OLED display panel.

In some embodiments, with reference to FIG. 2, the pixel defining structure 31 includes a top surface 311 away from the base substrate 1, and the top surface 311 has a shape of a convex cambered surface. Therefore, after the reflow process is performed, the surface of the pixel defining structure 31 is rounded and the other film layers subsequently evaporated on the rounded pixel defining structure 31 are is less likely to break, which is beneficial to the formation of other continuous OLED organic film layers and a continuous cathode film layer in the subsequent second evaporation stage. As such, the voltage of the OLED device may be reduced and the light emission efficiency of the OLED device may be improved, thereby facilitating the realization of the high brightness display of the OLED display panel.

In some other embodiments, with continued reference to FIG. 2, the first portion 51 of the first film layer group includes an end 511 proximate to the pixel defining structure 31. The end 511 is covered by the pixel defining structure 31 and is inserted between the pixel defining structure 31 and the first electrode layer 2. By covering the end 511 of the first portion of the first film layer group with the pixel defining structure 31, the pixel defining structure 31 having the rounded surface is formed, while the first portion 51 of the first film layer group and the second portion 52 of the first film layer group are completely interrupted, so that the lateral electricity leakage between the pixels may be greatly reduced, which is beneficial to the improvement of the yield of the display panel and the resolution of the display panel.

In some other embodiments, with continued reference to FIG. 2, a thickness of the end 511 is less than a thickness of a remaining part of the first portion 51 of the first film layer group other than the end 511; and/or, the thickness of the end 511 is less than a thickness of the second portion 52 of the first film layer group.

In some other embodiments, with continued reference to FIG. 2, the orthographic projection of the first portion 51 of the first film layer group on the base substrate 1 partially overlaps with the orthographic projection of the second portion 52 of the first film layer group on the base substrate.

In some other embodiments, with continued reference to FIG. 2, part of the second film layer group 6 is filled in a gap 7 between the first portion 51 of the first film layer group and the second portion 52 of the first film layer group. Since the second film layer group 6 mainly includes some organic film layer materials with low conductivity, by filling the gap 7 between the first portion 51 of the first film layer group and the second portion 52 of the first film layer group with the second film layer group 6, it is possible to further reduce the probability of the lateral electricity leakage between the first portion 51 of the first film layer group and the second portion 52 of the first film layer group, which is in turn beneficial to the improvement of the yield of the display panel and the resolution of the display panel.

In some other embodiments, with continued reference to FIG. 2, a part of the second film layer group 6 filled in the gap 7 is in direct contact with the top surface 311 of the pixel defining structure 31. Since the second film layer group 6 is in direct contact with the top surface 311 of the pixel defining structure, it is beneficial to the formation of a continuous film layer structure of the second film layer group 6 Accordingly, it is possible to further ensure the continuity of the cathode film layer in the second film layer group 6, thereby reducing the voltage of the OLED device and improving the light emission efficiency of the OLED device, which may in turn facilitate the realization of the high brightness display of the OLED display panel.

In some other embodiments, with continued reference to FIG. 2, a tangent plane 81 of the top surface 311 of the pixel defining structure at a first position 8 has an included angle a with respect to a first surface 11 of the base substrate 1, where the included angle a is less than or equal to 60 degrees. The first surface 11 of the base substrate 1 is a surface of the base substrate 1 facing the first electrode layer 2. The first position 8 is a position where the top surface 311 of the pixel defining structure contacts with the first film layer group 5. When performing the reflow process, the contour of the pixel defining structure 31 may be controlled during the reflow by adjusting process parameters of the high temperature treatment, ultraviolet irradiation, the combination of the ultraviolet irradiation and the high-temperature treatment, etc., so as to ensure that the included angle a of the tangent plane 81 of the top surface 311 of the pixel defining structure at the first position 8 with respect to the first surface 11 of the base substrate 1 is less than or equal to 60 degrees. In this way, it is possible for the pixel defining structure 31 to not only interrupt the first portion 51 of the first film layer group and the second portion 52 of the first film layer group effectively, but also facilitate the filling of part of the subsequently manufactured second film layer group 6 into the gap 7 between the first portion 51 of the first film layer group and the second portion 52 of the first film layer group to come into direct contact with the top surface 311 of the pixel defining structure, thereby facilitating the continuity of the second film layer group 6.

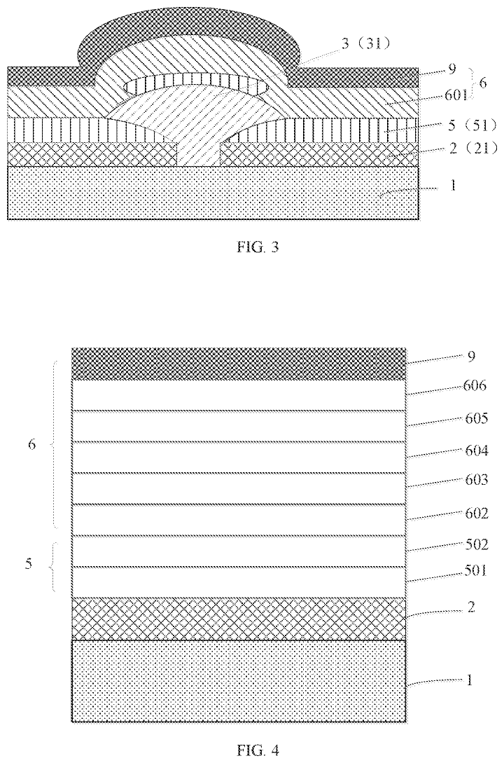

FIG. 3 shows a schematic cross-sectional view of a display substrate taken along line AA′ in FIG. 1, according to some other exemplary embodiments of the present disclosure.

In this embodiment, with reference to FIG. 3, the display substrate includes: the base substrate 1; the first electrode layer 2 disposed on the base substrate 1; the pixel defining layer 3 disposed on the side of the first electrode layer 2 away from the base substrate 1; the first film layer group 5 disposed on the side of the pixel defining layer 3 away from the base substrate 1; and a second film layer group 6 disposed on the side of the first film layer group 5 away from the base substrate 1, where the second film layer group 6 includes at least a second electrode layer 9. The second film layer group 6 is manufactured through the second evaporation stage. Before the second electrode layer 9 is manufactured, all other OLED functional layers 601 other than the first film layer group 5 and the second electrode layer 9 need to be evaporated first. The functional layer 601 is disposed between the first film layer group 5 and the second electrode layer 9. Since the functional layer 601 is filled in the gap between the first portion 51 of the first film layer group and the second portion 52 of the first film layer group and the continuous functional layer 601 is formed, the second electrode layer 9 which is formed on the functional layer 601 is also continuous, so that the voltage of the OLED device may be reduced and the light emission efficiency of the OLED device may be improved, thereby facilitating realization of the high brightness and high resolution display of the OLED display panel.

The light-emitting units in the OLED display panel may adopt a single-layer OLED device or a Tandem OLED device. The single-layer OLED device has a simple structure, a manufacturing process thereof is mature, and a product yield thereof is high.

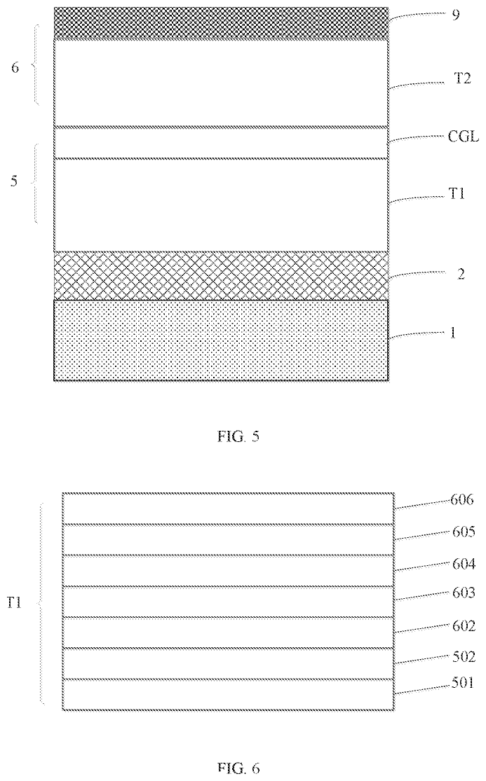

FIG. 4 shows a schematic diagram of a structure of a single-layer OLED device of a light-emitting unit according to some exemplary embodiments of the present disclosure.

In this embodiment, with reference to FIG. 3 and FIG. 4, the display substrate further includes: a hole injection layer 501 disposed on the side of the first electrode layer 2 away from the base substrate 1; a hole transport layer 502 disposed on a side of the hole injection layer 501 away from the base substrate 1; an electron barrier layer 602 disposed on a side of the hole transport layer 502 away from the base substrate 1; a light-emitting layer 603 disposed on a side of the electron barrier layer 602 away from the base substrate 1; a hole barrier layer 604 disposed on a side of the light-emitting layer 603 away from the base substrate 1; an electron transfer layer 605 disposed on a side of the hole barrier layer 604 away from the base substrate 1; an electron injection layer 606 disposed on a side of the electron transfer layer 605 away from the base substrate 1; and the second electrode layer 9 disposed on a side of the electron injection layer 606 away from the base substrate 1. The first film layer group 5 includes the hole injection layer 501 and the hole transport layer 502, and/or, the second film layer group 6 includes the electron barrier layer 602, the light-emitting layer 603, the hole barrier layer 604, the electron transport layer 605, the electron injection layer 606 and the second electrode layer 9.

In this embodiment, since the hole injection layer 501 and the hole transport layer 502 have high conductivity, and they are required to be interrupted by the pixel defining structure 31. The first film layer group 5 is manufactured in the first evaporation stage, and the first film layer group 5 includes the hole injection layer 501 and the hole transport layer 502. Since the first evaporation stage is completed before the reflow process is performed on the pixel defining structure 31, the first film layer group 5 may be interrupted by the pixel defining structure 31 effectively, which may effectively reduce the lateral electricity leakage. The electron barrier layer 602, the light-emitting layer 603, the hole barrier layer 604, the electron transport layer 605, and the electron injection layer 606 have low conductivity, and even if they are formed as continuous film layers, the lateral current is less likely to be generated. Accordingly, the electron barrier layer 602, the light-emitting layer 603, the hole barrier layer 604, the electron transport layer 605 and the electron injection layer 606 are manufactured in the second evaporation stage. The second evaporation stage is performed after the reflow process is performed on the pixel defining structure 31. At this time, the pixel defining structure 31 has formed with the rounded contour, as shown in FIG. 2, therefore, the electron barrier layer 602, the light-emitting layer 603, the hole barrier layer 604, the electron transport layer 605 and the electron injection layer 606 are gradually filled into the gap 7 formed by the first film layer group 5 on the surface of the pixel defining structure 31, so as to form the continuous film layers. Further, the second electrode layer 9 is formed on the side of the electron injection layer 606 away from the base substrate 1. As the electron barrier layer 602, the light-emitting layer 603, the hole barrier layer 604, the electron transport layer 605, and the electron injection layer 606 are formed as the continuous film layers, the second electrode layer 9 manufactured is also a continuous film layer, so as to reduce the voltage of the OLED device and improve the light emission efficiency of the OLED device, thereby facilitating the realization of the high brightness and high resolution display of the OLED display panel.

The light-emitting units in the OLED display substrate may also adopt a Tandem OLED device. The tandem (Tandem) OLED device is formed by stacking a plurality of individual OLED light-emitting structures through one or more charge generating layers and connecting them in series. The Tandem OLED device may include two, three, or more light-emitting structures. The number of light-emitting structures and the efficiency and lifetime of the tandem (Tandem) OLED devices are closely related. Through the stacking technology, the efficiency of the OLED device may be further improved, thereby facilitating the high brightness display of the OLED display panel and the lifetime improvement of the OLED display panel.

FIG. 5 shows a schematic diagram of a structure of a double-layer OLED device of a light-emitting unit according to some exemplary embodiments of the present disclosure.

In this embodiment, the display substrate further includes: a first stacked film layer group T1 disposed on a side of the first electrode layer 2 away from the base substrate 1; a charge generation layer CGL disposed on a side of the first stacked film layer group T1 away from the base substrate 1; a second stacked film layer group T2 disposed on a side of the charge generation layer CGL away from the base substrate 1; and the second electrode layer 9 disposed on a side of the second stacked film layer group T2 away from the base substrate 1. The first film layer group 5 includes the first stacked film layer group T1 and the charge generation layer CGL, and/or, the second film layer group 6 includes the second stacked film layer group T2 and the second electrode layer 9.

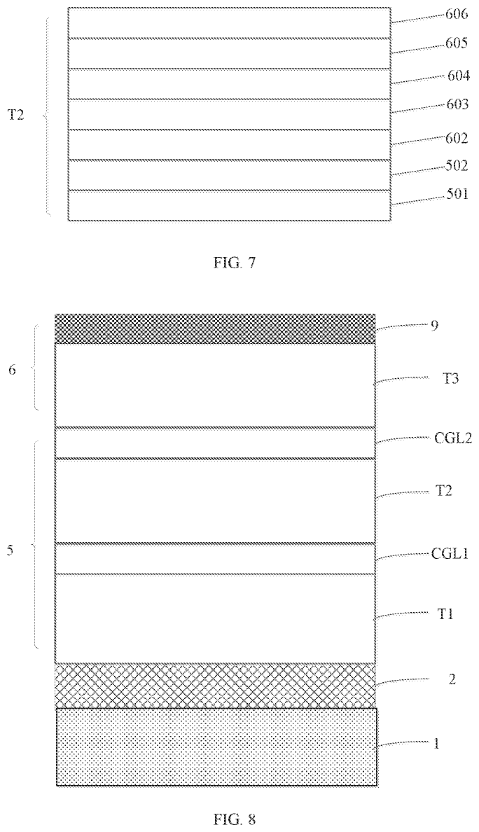

FIG. 6 shows a schematic diagram of a structure of a first stacked film layer group T1 in FIG. 5. FIG. 7 shows a schematic diagram of a structure of a second stacked film layer group T2 in FIG. 5.

For example, with reference to FIG. 5, FIG. 6 and FIG. 7, the first stacked film layer group T1 includes: a hole injection layer 501 disposed on a side of the first electrode layer 2 away from the base substrate 1; a hole transport layer 502 disposed on a side of the hole injection layer 501 away from the base substrate 1; an electron barrier layer 602 disposed on a side of the hole transport layer 502 away from the base substrate 1; a light-emitting layer 603 disposed on a side of the electron barrier layer 602 away from the base substrate 1; a hole barrier layer 604 disposed on a side of the light-emitting layer 603 away from the base substrate 1; an electron transfer layer 605 disposed on a side of the hole barrier layer 604 away from the base substrate 1; and an electron injection layer 606 disposed on a side of the electron transfer layer 605 away from the base substrate 1, and/or, the second stacked film layer group T2 includes: a hole injection layer 501 disposed on a side of the charge generation layer CGL away from the base substrate 1; a hole transport layer 502 disposed on a side of the hole injection layer 501 away from the base substrate 1; an electron barrier layer 602 disposed on a side of the hole transport layer 502 away from the base substrate 1; a light-emitting layer 603 disposed on a side of the electron barrier layer 602 away from the base substrate 1; a hole barrier layer 604 disposed on a side of the light-emitting layer 603 away from the base substrate 1; an electron transfer layer 605 disposed on a side of the hole barrier layer 604 away from the base substrate 1; and an electron injection layer 606 disposed on a side of the electron transport layer 605 away from the base substrate 1.

In an aspect, the light emission efficiency of the double-layer OLED device is significantly improved compared to the light emission efficiency of the single-layer OLED device, thus by using the double-layer structure, it is possible to achieve higher brightness per unit area, facilitating the realization of the high brightness display of the OLED display panel. In another aspect, the first film layer group 5 includes the first stacked film layer group T1 and the charge generation layer CGL, and the first stacked film layer group T1 and the charge generation layer CGL are each interrupted by the pixel defining structure, so that it is possible to effectively reduce the lateral electricity leakage between the pixel units; the second film layer group 6 includes the second stacked film layer group T2 and the second electrode layer 9, and the second film layer group 6 is manufactured after the reflow process is performed on the pixel defining structure 31, so that it is possible to ensure the continuity of the film layer of the second electrode layer 9. In this way, the voltage of the OLED device may be reduced and the light emission efficiency of the OLED device may be improved, which in turn facilitates the realization of the high brightness and high resolution display of the OLED display panel.

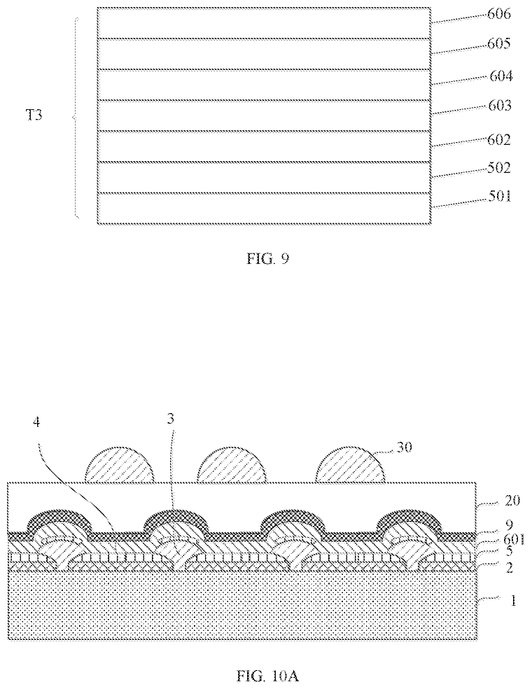

FIG. 8 shows a schematic diagram of a structure of a three-layer OLED device of a light-emitting unit according to some exemplary embodiments of the present disclosure. FIG. 9 shows a schematic diagram of a structure of a third stacked film layer group in the three-layer OLED device in FIG. 8.

In this embodiment, the display substrate includes: the first stacked film layer group T1 disposed on the side of the first electrode layer 2 away from the base substrate 1; the first charge generation layer CGL1 disposed on the side of the first stacked film layer group T1 away from the base substrate 1; the second stacked film layer group T2 disposed on the side of the first charge generation layer CGL1 away from the base substrate 1; a second charge generation layer CGL2 disposed on the side of the second stacked film layer group T2 away from the base substrate 1; a third stacked film layer group T3 disposed on a side of the second charge generation layer CGL2 away from the base substrate 1; and the second electrode layer 9 disposed on a side of the third stacked film layer group T3 away from the base substrate 1. The first film layer group 5 includes the first stacked film layer group T1, the first charge generation layer CGL1, the second stacked film layer group T2 and the second charge generation layer CGL2, and/or, the second film layer group 6 includes the third stacked film layer group T3 and the second electrode layer 9.

For example, with reference to FIG. 6, FIG. 7, FIG. 8 and FIG. 9, the first stacked film layer group T1 includes: the hole injection layer 501 disposed on the side of the first electrode layer 2 away from the base substrate 1; the hole transport layer 502 disposed on the side of the hole injection layer 501 away from the base substrate 1; an electron barrier layer 602 disposed on the side of the hole transport layer 502 away from the base substrate 1; the light-emitting layer 603 disposed on the side of the electron barrier layer 602 away from the base substrate 1; the hole barrier layer 604 disposed on the side of the light-emitting layer 603 away from the base substrate 1; an electron transfer layer 605 disposed on the side of the hole barrier layer 604 away from the base substrate 1; and the electron injection layer 606 disposed on the side of the electron transfer layer 605 away from the base substrate 1, and/or, the second stacked film layer group T2 includes: the hole injection layer 501 disposed on the side of the charge generation layer CGL1 away from the base substrate 1; the hole transport layer 502 disposed on the side of the hole injection layer 501 away from the base substrate 1; the electron barrier layer 602 disposed on the side of the hole transport layer 502 away from the base substrate 1; the light-emitting layer 603 disposed on the side of the electron barrier layer 602 away from the base substrate 1; the hole barrier layer 604 disposed on the side of the light-emitting layer 603 away from the base substrate 1; the electron transfer layer 605 disposed on the side of the hole barrier layer 604 away from the base substrate 1; and the electron injection layer 606 disposed on the side of the electron transport layer 605 away from the base substrate 1, and/or, the third stacked film layer group T3 includes: a hole injection layer 501 disposed on the side of the charge generation layer CGL2 away from the base substrate 1; a hole transport layer 502 disposed on a side of the hole injection layer 501 away from the base substrate 1; an electron barrier layer 602 disposed on a side of the hole transport layer 502 away from the base substrate 1; a light-emitting layer 603 disposed on a side of the electron barrier layer 602 away from the base substrate 1; a hole barrier layer 604 disposed on a side of the light-emitting layer 603 away from the base substrate 1; an electron transfer layer 605 disposed on a side of the hole barrier layer 604 away from the base substrate 1; and an electron injection layer 606 disposed on a side of the electron transport layer 605 away from the base substrate 1.

Compared to the single-layer OLED device and the double-layer OLED device, the three-layer OLED device has higher efficiency and may provide higher display brightness. In addition, the first film layer group 5 includes the first stacked film layer group T1, the first charge generation layer CGL1, the second stacked film layer group T2 and the second charge generation layer CGL2, and the first film layer group 5 is interrupted by the pixel defining structure 31, which may effectively reduce the lateral electricity leakage between the pixel units. The second film layer group 6 includes the third stacked film layer group T3 and the second electrode layer 9, and the second film layer group 6 is manufactured after the reflow process is performed on the pixel defining structure 31, so that it is possible to ensure the continuity of the film layer of the second electrode layer 9. In this way, the voltage of the OLED device may be reduced and the light emission efficiency of the OLED device may be improved, which in turn facilitates the realization of the high brightness and high resolution display of the OLED display panel.

It will be noted that the first stacked film layer group T1, the second stacked film layer group T2, and the third stacked film layer group T3 are only illustrative explanations of the structure of each stacked film layer group. The film layer thickness, doping concentration, material type, etc. of the first stacked film layer group T1, the second stacked film layer group T2 and the third stacked film layer group T3 are not exactly the same, and may be designed according to actual needs, The various stacked layer groups in the present disclosure may adopt the various designs known in the art, which is not be limited in the embodiments of the present disclosure.

In the embodiments of the present disclosure, only examples of the single-layer OLED device, the double-layer OLED device and the three-layer OLED device are schematically described. In fact, the design provided in the embodiments of the present disclosure is also applicable to a four-layer OLED device or an OLED device of more stacked layers.

For example, in some embodiments, with reference to FIG. 2, the pixel defining layer 3 includes a photoresist material.

For example, in some embodiments, with reference to FIG. 2, the photoresist material is reflowable after being softened, and a softening temperature of the photoresist material is lower than a glass transition temperature of each film layer of the first film layer group 5 and the second film layer group 6. By selecting the photoresist material with the low softening temperature, it is ensured that the softening temperature of the photoresist material is lower than the glass transition temperature of each organic material of the light-emitting device In this way, it may be ensured that the reflow process is performed at a low temperature, avoiding a change in the nature of the evaporated organic material during the reflow process and preventing the efficiency decrease of the light-emitting unit caused by the change of the nature of the evaporated organic material to affect the display effect of the display panel.

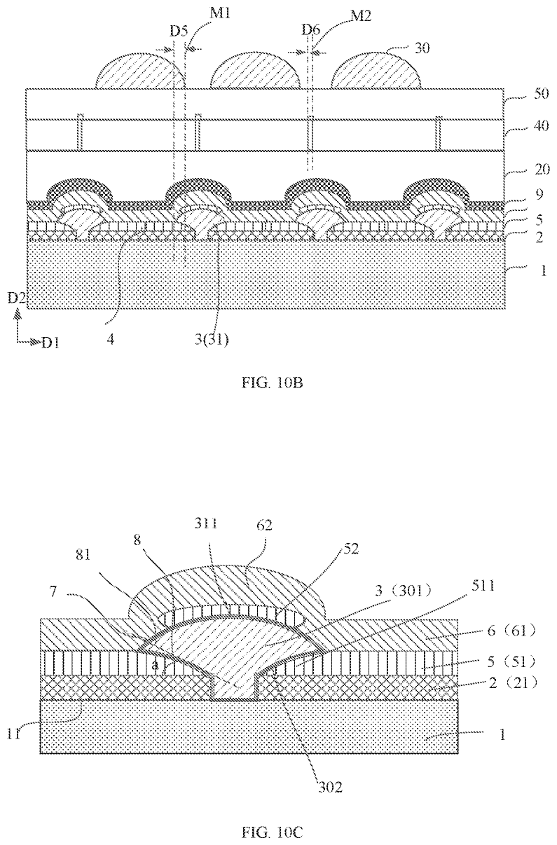

FIG. 10A shows a schematic partial cross-sectional view of a display substrate according to some other exemplary embodiments of the present disclosure. FIG. 10B shows a schematic partial cross-sectional view of a display substrate according to some other exemplary embodiments of the present disclosure, in which a color film layer is shown. FIG. 10C shows a schematic partial cross-sectional view of a display substrate according to some other exemplary embodiments of the present disclosure, in which a first sub-pixel defining layer and a second sub-pixel defining layer are shown.

For example, in some embodiments, with reference to FIG. 10A, the display substrate further includes an encapsulation layer 20 disposed on a side of the second electrode layer 9 away from the base substrate 1, and a plurality of micro lenses 30 disposed on a side of the encapsulation layer 20 away from the base substrate 1. Orthographic projections of the plurality of micro lenses 30 on the base substrate 1 are each located within an orthographic projection of a respective pixel opening 4 on the base substrate 1. By the configuration of the plurality of micro lenses 30, light extraction efficiency of the OLED light-emitting units may be increased, so that more photons are emitted out of the display panel, and the high brightness display of the display panel may be realized.

For example, in some embodiments, with reference to FIG. 10A, a material of the plurality of micro lenses 30 is the same as a material of at least a part of the pixel defining layer 3.

For example, in some embodiments, with reference to FIG. 10A, a curvature of at least one micro lens 30 is smaller than a curvature of the pixel defining structure 31.

For example, in some embodiments, with reference to FIG. 10B, the display substrate may further include a plurality of color film layers 40 disposed on a side of the encapsulation layer 20 away from the base substrate 1; a planarization layer 50 disposed on a side of the color film layer 40 away from the base substrate 1, and a plurality of micro lenses 30 disposed on a side of the planarization layer 50 away from the base substrate 1. An orthographic projection of the micro lens 30 on the base substrate 1 and an orthographic projection of the pixel defining structure 31 adjacent to the micro lens 30 on the base substrate 1 have a first overlap portion M1, and a width of the first overlap portion M1 in the first direction is D5. Adjacent color film layers 40 may be overlapped with each other in an edge region, and the overlap region of the adjacent color film layers 40 serves as a black matrix. Orthographic projections of the plurality of adjacent color film layers 40 on the base substrate 1 have a second overlap portion M2, and a width of the second overlap portion M2 in the first direction is D6.

On the one hand, the pixel defining layer 3 converges stray light to the black matrix, and since the curvature of the micro lens 30 is smaller than the curvature of the pixel defining structure 31, the black matrix may reduce optical crosstalk between the pixels. On the other hand, the width D5 of the first overlap portion M1 formed by the orthographic projection of the adjacent micro lens 30 on the base substrate 1 and the orthographic projection of the pixel defining structure 31 on the base substrate 1 is greater than the width D6 of the second overlap portion M2 formed by the overlap of the corresponding adjacent color film layers 40, so that more effective light from the light-emitting region may be converged and thereby improving the brightness of the display substrate.

For example, the pixel defining layer 3 may include a light absorbing material. In this way, it is possible to control the stray light between the pixels.

For example, in some embodiments, with reference to FIG. 10C, the pixel defining layer may further include a first sub-pixel defining layer 301 and a second sub-pixel defining layer 302. The second sub-pixel defining layer 302 is disposed on a side of the first sub-pixel defining layer 301 away from the base substrate 1. An orthographic projection of the second sub-pixel defining layer 302 on the base substrate 1 at least partially overlaps with an orthographic projection of the first sub-pixel defining layer 301 on the base substrate 1. The first sub-pixel defining layer 301 includes a photoresist material, and the second sub-pixel defining layer 302 includes an inorganic material. That is, in this embodiment, the pixel defining layer includes an organic layer and an inorganic layer, and the inorganic layer covers the organic layer. In the actual manufacturing process, the organic layer and the inorganic layer of the pixel defining layer may be manufactured before the deposition of the light-emitting functional layer. For example, the organic layer and the inorganic layer of the pixel defining layer may be manufactured using the same patterning process. In this way, the inorganic layer covering the organic layer may prevent water, oxygen and the like from affecting the performance of the subsequently formed light-emitting element.

Some exemplary embodiments of the present disclosure further provide a display apparatus. The display apparatus includes any display substrate as described above.

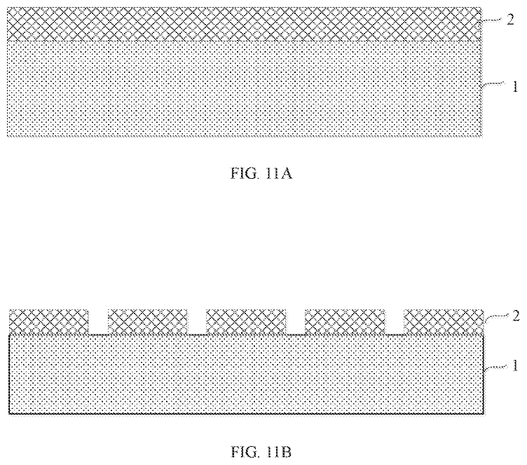

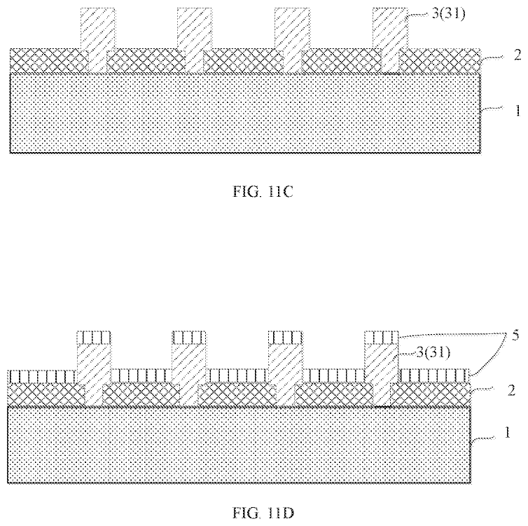

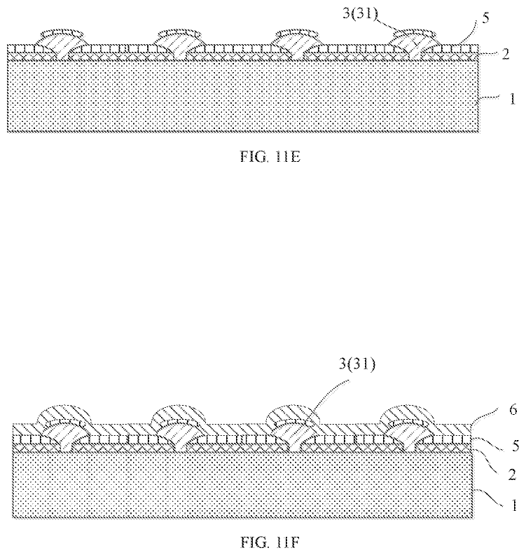

FIG. 11A to FIG. 11F show a method for manufacturing a display panel according to an exemplary embodiment of the present disclosure. As shown in FIG. 11A to FIG. 11F, the method may include steps S01 to S05.

It will be noted that some steps of the above manufacturing method may be performed separately or in combination, and in parallel or sequentially, and are not limited to the specific operation sequence shown in the figures.

In step S01, with reference to FIG. 1, FIG. 2, FIG. 11A and FIG. 11B, a first electrode material layer is formed on the base substrate 1, and a patterning process is performed on the first electrode material layer, so as to form a first electrode layer 2 including a plurality of first electrode patterns 21. The plurality of first electrode patterns 21 are arranged in an array along a first direction D1 and a second direction D2 on the base substrate 1, and are spaced apart from each other along each of the first direction D1 and the second direction D2.

In step S02, with reference to FIG. 1, FIG. 2 and with reference to FIG. 11C, a pixel defining material layer is formed on a side of the first electrode layer 2 away from the base substrate 1, and a patterning process is performed on the pixel defining material layer, so as to form a pixel defining layer 3 including a plurality of pixel defining structures 31. The plurality of pixel defining structures 31 are arranged in an array along the first direction D1 and the second direction D2 on the base substrate 1. The plurality of pixel defining structures 31 define a plurality of pixel openings 4, each of which exposes a portion of a respective one of the plurality of first electrode patterns 21.

In step S03, with reference to FIG. 2 and FIG. 11D, a first film layer group 5 is formed on a side of the pixel defining layer 3 away from the base substrate 1 by using a first evaporation process. The first film layer group 5 includes at least one film layer.

In step S04, with reference to FIG. 2 and FIG. 11E, a reflow process is performed on the base substrate formed with the pixel defining layer 3 and the first film layer group 5, so as to round a contour of the pixel defining structure 31.

In step S05, with reference to FIG. 2 and FIG. 11F, a second film layer group 6 is formed on a side of the first film layer group 5 away from the base substrate 1 by using a second evaporation process, where the second film layer group 6 includes at least one film layer. With further reference to FIG. 2, the first film layer group 5 includes a first portion 51 and a second portion 52, an orthographic projection of the first portion 51 of the first film layer group on the base substrate 1 at least partially overlaps with an orthographic projection of at least one first electrode pattern 21 on the base substrate 1, and an orthographic projection of the second portion 52 of the first film layer group on the base substrate 1 at least partially overlaps with an orthographic projection of at least one pixel defining structure 31 on the base substrate 1. The first portion 51 of the first film layer group and the second portion 52 of the first film layer group are interrupted. The second film layer group 6 includes a first portion 61 and a second portion 62. An orthographic projection of the first portion 61 of the second film layer group on the base substrate 1 at least partially overlaps with an orthographic projection of at least one first electrode pattern 21 on the base substrate 1, an orthographic projection of the second portion 62 of the second film layer group at least partially overlaps with an orthographic projection of at least one pixel definition structure 31 on the base substrate 1. The first portion 61 of the second film layer group and the second portion 62 of the second film layer group extend continuously.

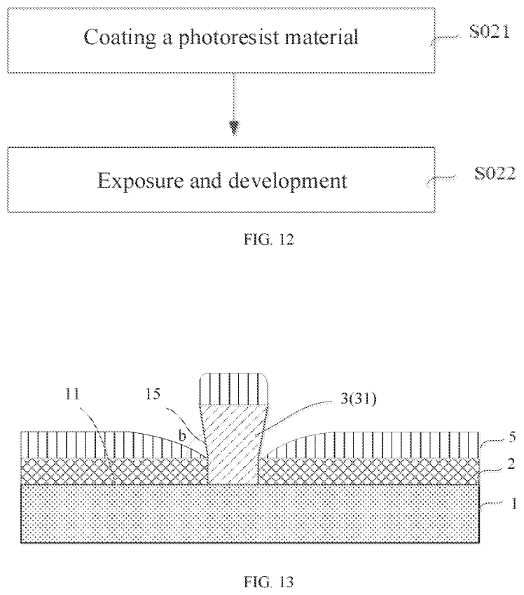

FIG. 12 shows a flowchart of manufacturing a pixel defining structure of a display substrate according to some exemplary embodiments of the present disclosure. The process includes S021 to S022.

For example, in some embodiments, with reference to FIG. 11C and FIG. 12, a pixel defining material layer is formed on a side of the first electrode layer 2 away from the base substrate 1, and a patterning process is performed on the pixel defining material layer, so as to form the pixel defining layer 3 including the plurality of pixel defining structures 31. Specifically, in step S021, a photoresist material is coated on a side of the first electrode layer 2 away from the base substrate 1, and in step S022, an exposure process and a development process are performed on the photoresist material, so as to form the plurality of pixel defining structures 31.

For example, in some embodiments, the photoresist material is reflowable after being softened, and a softening temperature of the photoresist material is lower than a glass transition temperature of each organic film layer in the first film layer group 5 and the second film layer group 6.

For example, in some embodiments, the method further includes: before the first evaporation process, performing a baking process on the base substrate formed with the pixel defining layer. The softening temperature of the photoresist material is higher than a baking temperature of the baking process.

FIG. 13 shows a partial cross-sectional view of a base substrate before a reflow process is performed, according to some exemplary embodiments of the present disclosure.

For example, in some embodiments, with reference to FIG. 13, before the reflow process, a top surface of the pixel defining structure 31 has an included angle b with respect to a first surface of the base substrate 1 at a second position 15, where the included angle b is greater than or equal to 85 degrees. The first surface 11 of the base substrate is a surface of the base substrate 1 facing the first electrode layer 2. The second position 15 is a position where the top surface of the pixel defining structure 31 contacts with the first electrode layer 2; and/or, after the reflow process, with reference to FIG. 2, a tangent plane 81 of the top surface 311 of the pixel defining structure 31 at the first position 8 has an included angle a with respect to the first surface 11 of the base substrate 1, where the included angle a is less than or equal to 60 degrees. The first surface 11 of the base substrate 1 is the surface of the base substrate 1 facing the first electrode layer 2. The first position 8 is a position where the top surface 311 of the pixel defining structure 31 contacts with the first film layer group 5.

By adding the reflow process between the two evaporation processes, it is possible to ensure that not only the first film layer group 5 may be completely interrupted in the first evaporation stage, but also the pixel defining structure 31 formed after the reflow process has the rounded contour, so that it is possible to ensure the continuity of the second film layer group 6 in the second evaporation stage. In some exemplary embodiments, the second film layer group 6 includes a second electrode layer 9, and the second electrode layer 9 also has film layer continuity, correspondingly. In this way, the voltage of the OLED device may be reduced, and the light emission efficiency of the OLED device may be improved, which facilitates the realization of the high brightness display of the OLED display panel.

Although some embodiments of the overall concept of the present disclosure have been shown and explained, those of ordinary skill in the art will understand that modifications may be made to these embodiments without departing from the principles and spirit of the overall concept of the present disclosure. The scope of the present disclosure is defined by the claims and their equivalents.

1. A display substrate, comprising:
a base substrate;
a first electrode layer disposed on the base substrate, wherein the first electrode layer comprises a plurality of first electrode patterns, the plurality of first electrode patterns are arranged in an array along a first direction and a second direction on the base substrate, and the plurality of first electrode patterns are spaced apart from each other along each of the first direction and the second direction;
a pixel defining layer disposed on a side of the first electrode layer away from the base substrate, wherein the pixel defining layer comprises a plurality of pixel defining structures, the plurality of pixel defining structures are arranged in an array along the first direction and the second direction on the base substrate and define a plurality of pixel openings, and the plurality of pixel openings each expose a portion of a respective one of the plurality of first electrode patterns;
a first film layer group disposed on a side of the pixel defining layer away from the base substrate, wherein the first film layer group comprises at least one film layer; and
a second film layer group disposed on a side of the first film layer group away from the base substrate, wherein the second film layer group comprises at least one film layer,
wherein the first film layer group comprises a first portion and a second portion, an orthographic projection of the first portion of the first film layer group on the base substrate at least partially overlaps with an orthographic projection of at least one first electrode pattern on the base substrate, an orthographic projection of the second portion of the first film layer group on the base substrate at least partially overlaps with an orthographic projection of at least one pixel defining structure on the base substrate, and the first portion of the first film layer group and the second portion of the first film layer group are interrupted; and
wherein the second film layer group comprises a first portion and a second portion, wherein an orthographic projection of the first portion of the second film layer group at least partially overlaps with an orthographic projection of at least one first electrode pattern on the base substrate, an orthographic projection of the second portion of the second film layer group on the base substrate at least partially overlaps with an orthographic projection of at least one pixel defining structure on the base substrate, and the first portion of the second film layer group and the second portion of the second film layer group extend continuously.

2. The display substrate of claim 1, wherein the pixel defining structure comprises a top surface away from the base substrate, and the top surface has a shape of convex cambered surface.

3. The display substrate of claim 1, wherein the first portion of the first film layer group comprises an end proximate to the pixel defining structure, the end is covered by the pixel defining structure, and the end is inserted between the pixel defining structure and the first electrode layer.

4. The display substrate of claim 3, wherein
a thickness of the end is less than a thickness of a remaining part of the first portion of the first film layer group other than the end; and/or,
the thickness of the end is less than a thickness of the second portion of the first film layer group.

5. The display substrate of any claim 1, wherein the orthographic projection of the first portion of the first film layer group on the base substrate partially overlaps with the orthographic projection of the second portion of the first film layer group on the base substrate.

6. The display substrate of claim 1, wherein a part of the second film layer group is filled in a gap between the first portion of the first film layer group and the second portion of the first film layer group.

7. The display substrate of claim 6, wherein the part of the second film layer group filled in the gap is in direct contact with a top surface of the pixel defining structure.

8. The display substrate of claim 1, wherein a tangent plane of a top surface of the pixel defining structure at a first position has an included angle with respect to a first surface of the base substrate, the included angle being less than or equal to 60 degrees, wherein the first surface of the base substrate is a surface of the base substrate facing the first electrode layer, and the first position is a position where the top surface of the pixel defining structure contacts with the first film layer group.

9. The display substrate of claim 1, wherein the display substrate comprises a second electrode layer disposed on the side of the first film layer group away from the base substrate, and the second film layer group comprises at least the second electrode layer.

10. The display substrate of claim 1, further comprising:
a hole injection layer disposed on the side of the first electrode layer away from the base substrate;
a hole transport layer disposed on a side of the hole injection layer away from the base substrate;
an electron barrier layer disposed on a side of the hole transport layer away from the base substrate;
a light-emitting layer disposed on a side of the electron barrier layer away from the base substrate;
a hole barrier layer disposed on a side of the light-emitting layer away from the base substrate;
an electron transport layer disposed on a side of the hole barrier layer away from the base substrate;
an electron injection layer disposed on a side of the electron transport layer away from the base substrate; and
a second electrode layer disposed on a side of the electron injection layer away from the base substrate,
wherein the first film layer group comprises the hole injection layer and the hole transport layer, and/or, the second film layer group comprises the electron barrier layer, the light-emitting layer, the hole barrier layer, the electron transport layer, the electron injection layer and the second electrode layer.

11. The display substrate of claim 1, further comprising:
a first stacked film layer group disposed on the side of the first electrode layer away from the base substrate;
a charge generation layer disposed on a side of the first stacked film layer group away from the base substrate;
a second stacked film layer group disposed on a side of the charge generation layer away from the base substrate; and
a second electrode layer disposed on a side of the second stacked film layer group away from the base substrate,
wherein the first film layer group comprises the first stacked film layer group and the charge generation layer, and/or, the second film layer group comprises the second stacked film layer group and the second electrode layer.

12. The display substrate of claim 11, wherein
the first stacked film layer group comprises:
a hole injection layer disposed on the side of the first electrode layer away from the base substrate;
a hole transport layer disposed on a side of the hole injection layer away from the base substrate;
an electron barrier layer disposed on a side of the hole transport layer away from the base substrate;
a light-emitting layer disposed on a side of the electron barrier layer away from the base substrate;
a hole barrier layer disposed on a side of the light-emitting layer away from the base substrate;
an electron transport layer disposed on a side of the hole barrier layer away from the base substrate; and
an electron injection layer disposed on a side of the electron transport layer away from the base substrate,
and/or,
the second stacked film layer group comprises:
a hole injection layer disposed on the side of the charge generation layer away from the base substrate;
a hole transport layer disposed on a side of the hole injection layer away from the base substrate;
an electron barrier layer disposed on a side of the hole transport layer away from the base substrate;
a light-emitting layer disposed on a side of the electron barrier layer away from the base substrate;
a hole barrier layer disposed on a side of the light-emitting layer away from the base substrate;
an electron transport layer disposed on a side of the hole barrier layer away from the base substrate; and
an electron injection layer disposed on a side of the electron transport layer away from the base substrate.

13. The display substrate of claim 1, further comprising:
a first stacked film layer group disposed on the side of the first electrode layer away from the base substrate;
a first charge generation layer disposed on a side of the first stacked film layer group away from the base substrate;
a second stacked film layer group disposed on a side of the first charge generation layer away from the base substrate;
a second charge generation layer disposed on a side of the second stacked film layer group away from the base substrate;
a third stacked film layer group disposed on a side of the second charge generation layer away from the base substrate; and
a second electrode layer disposed on a side of the third stacked film layer group away from the base substrate,
wherein the first film layer group comprises the first stacked film layer group, the first charge generation layer, the second stacked film layer group and the second charge generation layer, and/or, the second film layer group comprises the third stacked film layer group and the second electrode layer.

14. The display substrate of claim 13, wherein
the first stacked film layer group comprises:
a hole injection layer disposed on a side of the first electrode layer away from the base substrate;
a hole transport layer disposed on a side of the hole injection layer away from the base substrate;
an electron barrier layer disposed on a side of the hole transport layer away from the base substrate;
a light-emitting layer disposed on a side of the electron barrier layer away from the base substrate;
a hole barrier layer disposed on a side of the light-emitting layer away from the base substrate;
an electron transport layer disposed on a side of the hole barrier layer away from the base substrate; and
an electron injection layer disposed on a side of the electron transport layer away from the base substrate,
and/or,
the second stacked film layer group comprises:
a hole injection layer disposed on the side of the first charge generation layer away from the base substrate;
a hole transport layer disposed on a side of the hole injection layer away from the base substrate;
an electron barrier layer disposed on a side of the hole transport layer away from the base substrate;
a light-emitting layer disposed on a side of the electron barrier layer away from the base substrate;
a hole barrier layer disposed on a side of the light-emitting layer away from the base substrate;
an electron transport layer disposed on a side of the hole barrier layer away from the base substrate; and
an electron injection layer disposed on a side of the electron transport layer away from the base substrate,
and/or,
the third stacked film layer group comprises:
a hole injection layer disposed on the side of the second charge generation layer away from the base substrate;
a hole transport layer disposed on a side of the hole injection layer away from the base substrate;
an electron barrier layer disposed on a side of the hole transport layer away from the base substrate;
a light-emitting layer disposed on a side of the electron barrier layer away from the base substrate;
a hole barrier layer disposed on a side of the light-emitting layer away from the base substrate;
an electron transport layer disposed on a side of the hole barrier layer away from the base substrate; and
an electron injection layer disposed on a side of the electron transport layer away from the base substrate.

15. The display substrate of claim 1, wherein the pixel defining layer comprises a photoresist material; and
wherein the photoresist material is reflowable after being softened, and a softening temperature of the photoresist material is lower than a glass transition temperature of each film layer of the first film layer group and a glass transition temperature of each film layer of the second film layer group.

16. (canceled)

17. The display substrate of claim 1, further comprising: a plurality of micro lenses disposed on a side of the second electrode layer away from the base substrate,
wherein each of orthographic projections of the plurality of micro lenses on the base substrate is located within an orthographic projection of a respective one of the plurality of pixel openings on the base substrate,
wherein a material of the plurality of micro lenses is the same as a material of at least a part of the pixel defining layer;
wherein a curvature of at least one of the micro lenses is less than a curvature of the pixel defining structure;
wherein the display substrate further comprises a plurality of color film layers, the plurality of color film layers are located between the pixel defining layer and a layer in which the plurality of micro lenses are located, wherein an orthographic projection of a micro lens on the base substrate and an orthographic projection of a pixel defining structure adjacent to the micro lens on the base substrate have a first overlap portion, orthographic projections of any two adjacent color film layers on the base substrate have a second overlap portion, and a width of the first overlap portion in the first direction is greater than a width of the second overlap portion in the first direction; and
wherein the pixel defining layer comprises a first sub-pixel defining layer and a second sub-pixel defining layer, the second sub-pixel defining layer is located on a side of the first sub-pixel defining layer away from the base substrate, and an orthographic projection of the second sub-pixel defining layer on the base substrate at least partially overlaps with an orthographic projection of the first sub-pixel defining layer on the base substrate; and the first sub-pixel defining layer comprises a photoresist material, and the second sub-pixel defining layer comprises an inorganic material.

18-21. (canceled)

22. A display apparatus comprising the display substrate of claim 1.

23. A method for manufacturing a display substrate, comprising:
forming a first electrode material layer on a base substrate, and performing a patterning process on the first electrode material layer, so as to form a first electrode layer comprising a plurality of first electrode patterns, wherein the plurality of first electrode patterns are arranged in an array along a first direction and a second direction on the base substrate, and the plurality of first electrode patterns are spaced apart from each other along each of the first direction and the second direction;
forming a pixel defining material layer on a side of the first electrode layer away from the base substrate, and performing a patterning process on the pixel defining material layer, so as to form a pixel defining layer comprising a plurality of pixel defining structures, wherein the plurality of pixel defining structures are arranged in an array along the first direction and the second direction on the base substrate, the plurality of pixel defining structures define a plurality of pixel openings, and the plurality of pixel openings each expose a portion of a respective one of the plurality of first electrode patterns;
forming a first film layer group on a side of the pixel defining layer away from the base substrate by using a first evaporation process, wherein the first film layer group comprises at least one film layer;
performing a reflow process on the base substrate formed with the pixel defining layer and the first film layer group; and
forming a second film layer group on a side of the first film layer group away from the base substrate by using a second evaporation process, wherein the second film layer group comprises at least one film layer,
wherein
the first film layer group comprises a first portion and a second portion, an orthographic projection of the first portion of the first film layer group on the base substrate at least partially overlaps with an orthographic projection of at least one first electrode pattern on the base substrate, an orthographic projection of the second portion of the first film layer group on the base substrate at least partially overlaps with an orthographic projection of at least one pixel defining structure on the base substrate, and the first portion of the first film layer group and the second portion of the first film layer group are interrupted; and
the second film layer group comprises a first portion and a second portion, wherein an orthographic projection of the first portion of the second film layer group on the base substrate at least partially overlaps with an orthographic projection of at least one first electrode pattern on the base substrate, an orthographic projection of the second portion of the second film layer group on the base substrate at least partially overlaps with an orthographic projection of at least one pixel defining structure on the base substrate, and the first portion of the second film layer group and the second portion of the second film layer group extend continuously.

24. The method of claim 23, wherein the forming a pixel defining material layer on a side of the first electrode layer away from the base substrate, and performing a patterning process on the pixel defining material layer, so as to form a pixel defining layer comprising a plurality of pixel defining structures, comprises:
coating a photoresist material on the side of the first electrode layer away from the base substrate; and
performing an exposure process and a development process on the photoresist material, so as to form the plurality of pixel defining structures,
wherein the photoresist material is reflowable after being softened, and a softening temperature of the photoresist material is lower than a glass transition temperature of each film layer of the first film layer group and a glass transition temperature of each film layer of the second film layer group;
wherein the method further comprises: before the first evaporation process, performing a baking process on the base substrate formed with the pixel defining layer; and
wherein a softening temperature of the photoresist material is higher than a baking temperature in the baking process.

25-26. (canceled)

27. The method of any ene of claim 23, wherein
before the reflow process, a top surface of the pixel defining structure has an included angle with respect to a first surface of the base substrate at a second position, the included angle being greater than or equal to 85 degrees, wherein the first surface of the base substrate is a surface of the base substrate facing the first electrode layer, and the second position is a position where the top surface of the pixel defining structure contacts with the first electrode layer; and/or,
after the reflow process, a tangent plane of the top surface of the pixel defining structure at a first position has an included angle with respect to the first surface of the base substrate, the included angle being less than or equal to 60 degrees, wherein the first surface of the base substrate is the surface of the base substrate facing the first electrode layer, and the first position is a position where the top surface of the pixel defining structure contacts with the first film layer group.
